(19) United States
(12) Patent Application Publication
(10) Pub. No.: US 2019/0252593 A1
(43) Pub. Date: Aug. 15, 2019

(54) THERMOELECTRIC CONVERSION DEVICE AND MANUFACTURING METHOD THEREOF

(71) Applicant: TDK CORPORATION, Tokyo (JP)

(72) Inventors: Makoto SHIBATA, Tokyo (JP); Takashi ASATANI, Tokyo (JP)

(73) Assignee: TDK CORPORATION, Tokyo (JP)

(21) Appl. No.: 16/270,977

(22) Filed: Feb. 8, 2019

(30) Foreign Application Priority Data
Feb. 13, 2018 (JP) 2018-023530

(51) Int. Cl. H01L 35/30; H01L 35/32; H01L 35/34

(52) U.S. Cl. CPC H01L 35/30; H01L 35/34; H01L 35/32

(57) ABSTRACT

A thermoelectric conversion device includes: at least one thermoelectric conversion element which is provided on a specific plane, and a heat transfer part which is thermally connected to the at least one thermoelectric conversion element, wherein the heat transfer part includes a separation portion which is disposed with a gap between the heat transfer part and at least a portion of the at least one thermoelectric conversion element, and a heat transfer portion which protrudes toward a side facing the at least one thermoelectric conversion element in a state where a portion thereof on a side opposite to the side facing the at least one thermoelectric conversion element is recessed, and is thermally connected to the at least one thermoelectric conversion element via the heat transfer portion.

### BACKGROUND

The present disclosure relates to a thermoelectric conversion device and a manufacturing method thereof.

Priority is claimed on Japanese Patent Application No. 2018-023530, filed on Feb. 13, 2018, the content of which is incorporated herein by reference.

In recent years, in view of energy saving, attention has been paid to the use of heat that is lost without being used. Especially, in fields related to internal combustion engines and combustion devices, research on thermoelectric conversion utilizing exhaust heat has been actively conducted.

For example, as shown in PCT International Publication No. 2011/065185 below, a thermoelectric conversion module (a thermoelectric conversion device) that includes a substrate formed to have a uniform thickness over the entire surface, a thermoelectric conversion film (a thermoelectric conversion element) formed on a first surface of the substrate, a first heat transfer part disposed on the first surface side of the substrate, and a second heat transfer part disposed on a second surface side of the substrate positioned on the opposite side of the first surface is known.

Protrusions are provided on one surface of each of the first heat transfer part and the second heat transfer part. The protrusions of the first heat transfer part are in contact with high temperature side electrodes formed at one end portion of the thermoelectric conversion film. The protrusions of the second heat transfer part are in contact with portions of the second surface of the substrate opposite to low temperature side electrodes formed at other end portion of the thermoelectric conversion film in a thickness direction of the substrate.

### SUMMARY

In the thermoelectric conversion device, it is desirable to reduce the distance from a heat receiving surface to a hot junction in order to efficiently transfer the heat received by the heat receiving surface of the first heat transfer part to the hot junction. On the other hand, since it is necessary to reduce transmission of the heat received by the heat receiving surface to a cold junction, it is desirable to lengthen the distance from the heat receiving surface to the cold junction.

However, in the thermoelectric conversion module described in Patent Document 1, the heat receiving surface of the heat transfer part is a uniform plane. Thus, if the distance from the heat receiving surface to the hot junction is shortened, the distance from the heat receiving surface to the cold junction also becomes short at the same time. For this reason, there has been a problem that it is impossible to increase a temperature difference between the hot junction and the cold junction, and thermoelectric conversion characteristics are not improved.

It is desirable to provide a thermoelectric conversion device and a manufacturing method thereof which make it possible to further improve thermoelectric conversion characteristics.

The present disclosure provides the following means.

A thermoelectric conversion device, including:

a thermoelectric conversion element provided on a specific plane; and a heat transfer part thermally connected to the thermoelectric conversion element,

in which the heat transfer part has a separation portion which is disposed with a gap between the heat transfer part and at least a portion of the thermoelectric conversion element, and a heat transfer portion which protrudes toward a side facing the thermoelectric conversion element in a state where a portion thereof on a side opposite to the side facing the at least one thermoelectric conversion element is recessed, and is thermally connected to the thermoelectric conversion element via the heat transfer portion.

BRIEF DESCRIPTION OF THE FIGURES

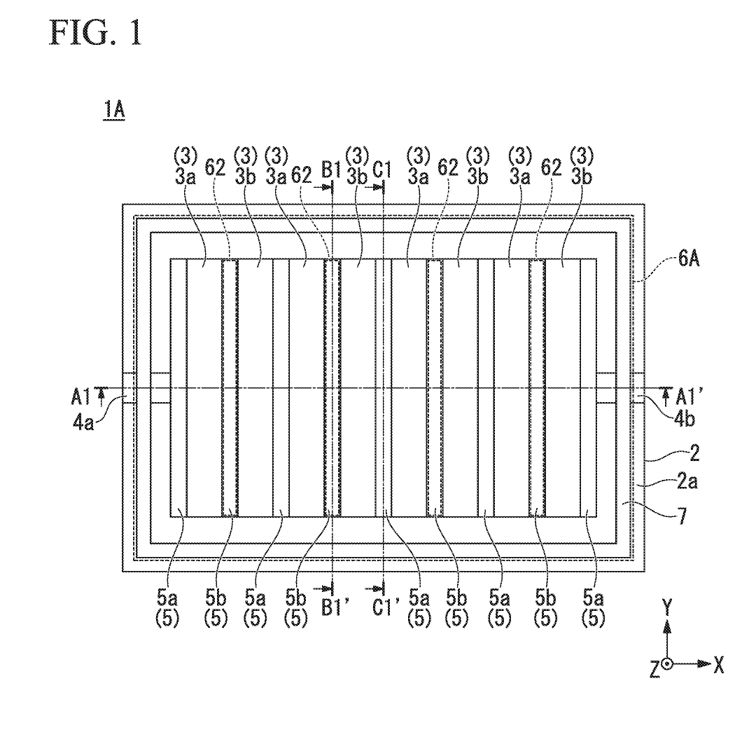

FIG. 1 is a transparent plan view showing a schematic configuration of a thermoelectric conversion device according to a first embodiment of the present disclosure.

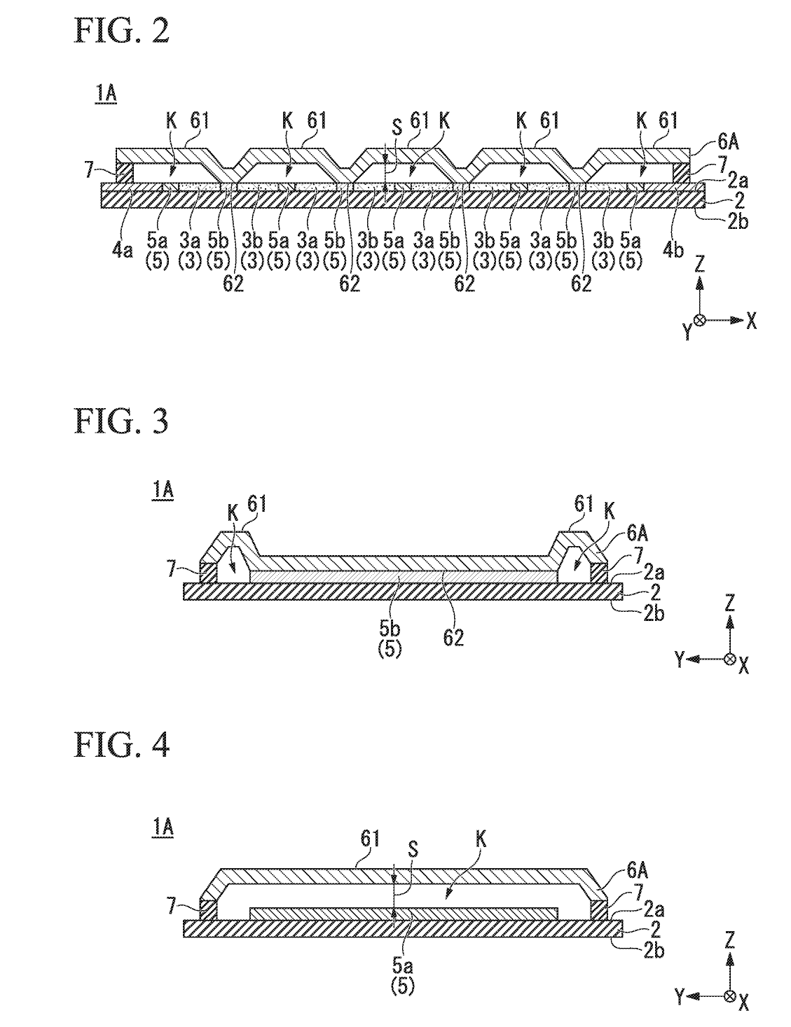

FIG. 2 is a cross-sectional view of the thermoelectric conversion device according to the line segment A1-A1′ shown in FIG. 1.

FIG. 3 is a cross-sectional view of the thermoelectric conversion device according to the line segment B1-B1′ shown in FIG. 1.

FIG. 4 is a cross-sectional view of the thermoelectric conversion device according to the line segment C1-C1′ shown in FIG. 1.

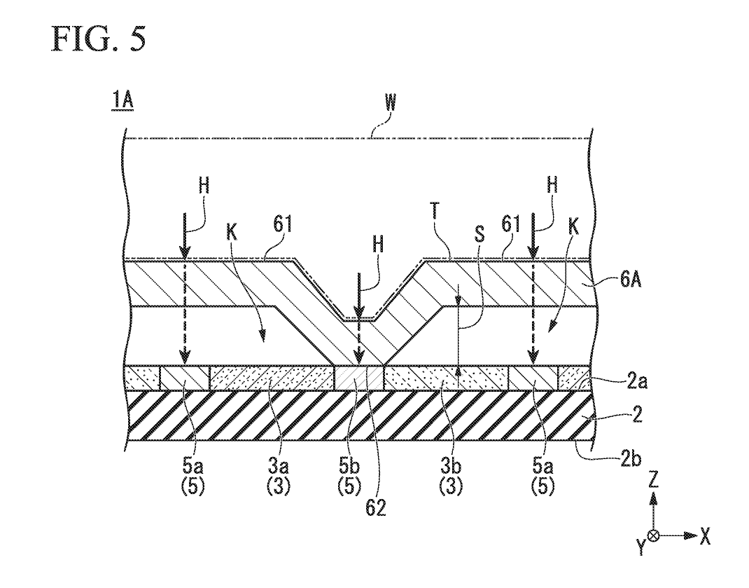

FIG. 5 is an enlarged cross-sectional view of a portion of the thermoelectric conversion device shown in FIG. 2.

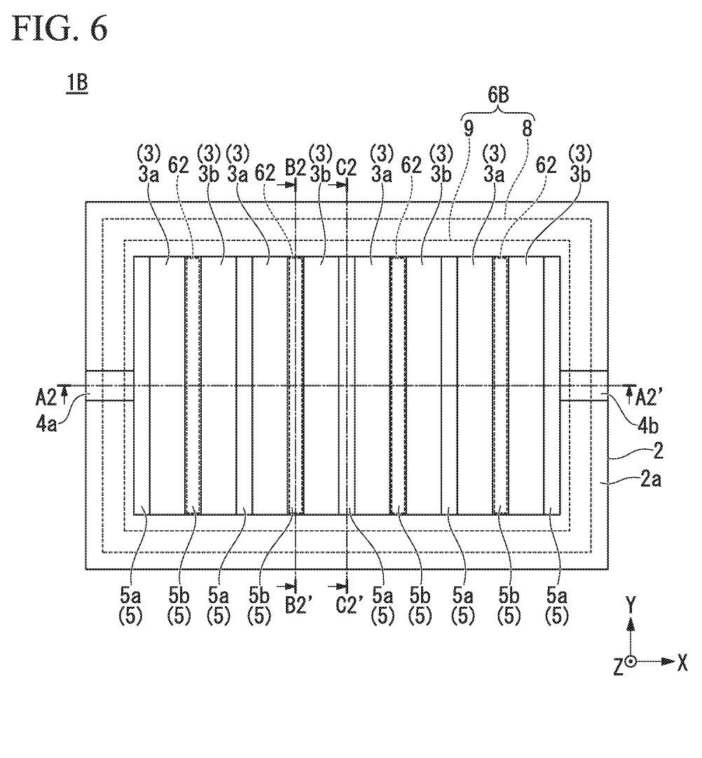

FIG. 6 is a transparent plan view showing a schematic configuration of a thermoelectric conversion device according to a second embodiment of the present disclosure.

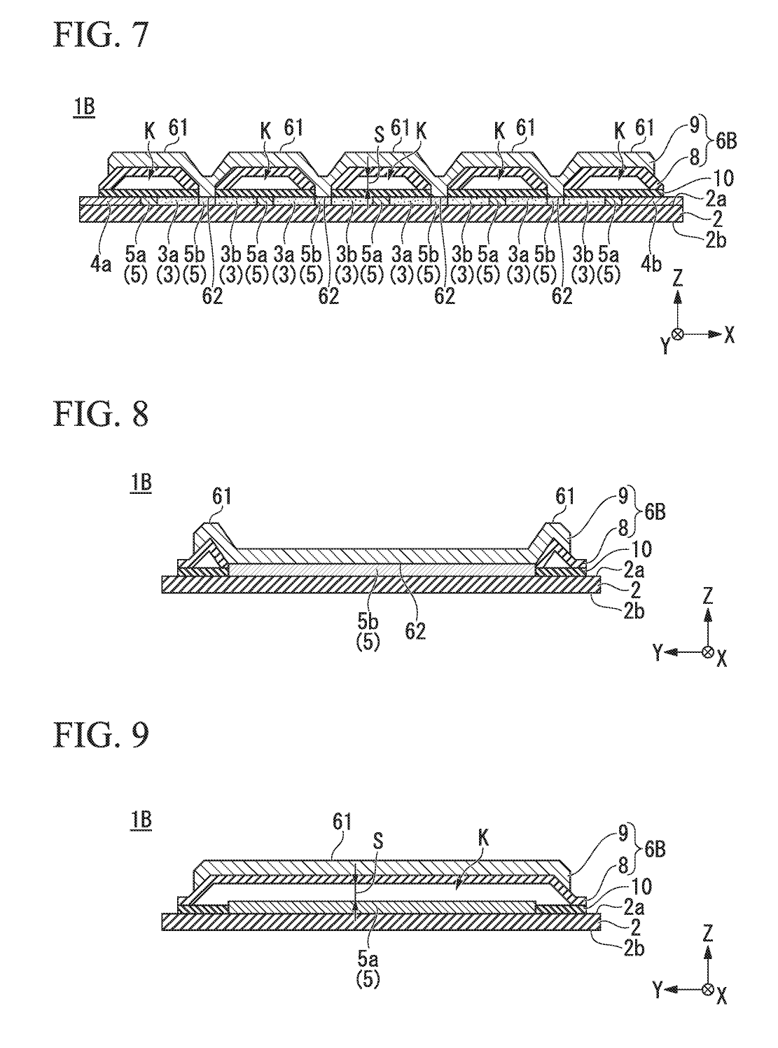

FIG. 7 is a cross-sectional view of the thermoelectric conversion device according to the line segment A2-A2′ shown in FIG. 6.

FIG. 8 is a cross-sectional view of the thermoelectric conversion device according to the line segment B2-B2′ shown in FIG. 6.

FIG. 9 is a cross-sectional view of the thermoelectric conversion device according to the line segment C2-C2′ shown in FIG. 6.

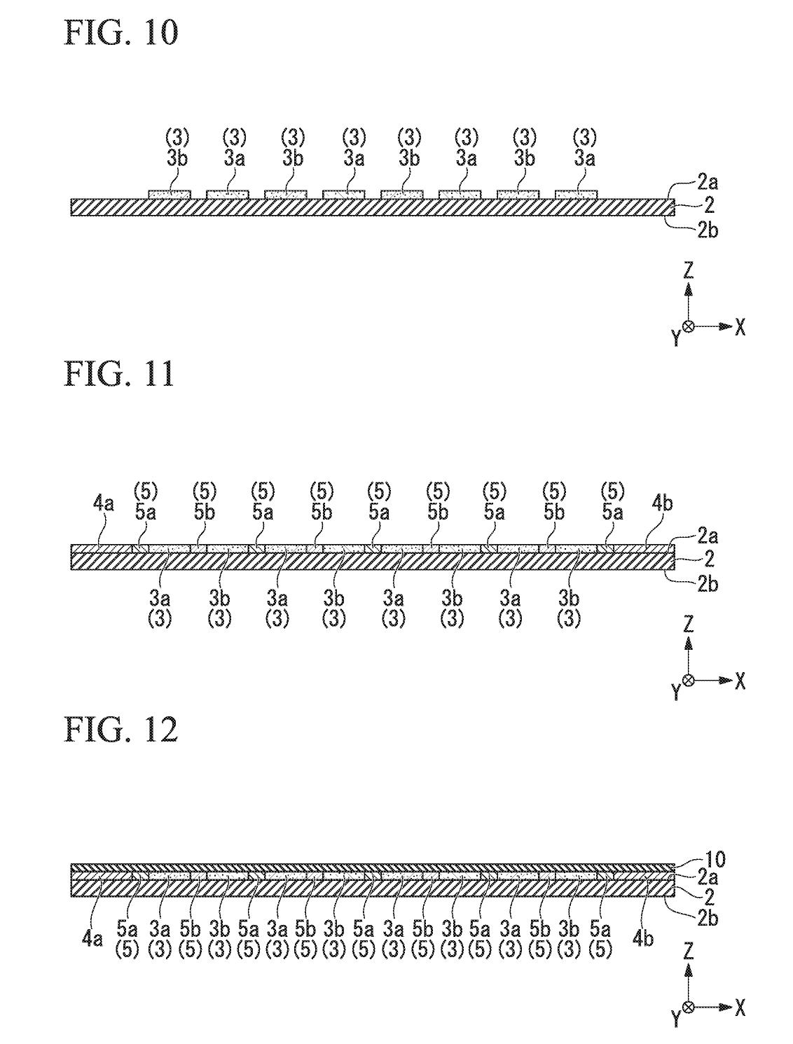

FIG. 10 is a cross-sectional view for sequentially explaining a manufacturing process of the thermoelectric conversion device shown in FIG. 6.

FIG. 11 is a cross-sectional view for sequentially explaining a manufacturing process of the thermoelectric conversion device shown in FIG. 6.

FIG. 12 is a cross-sectional view for sequentially explaining a manufacturing process of the thermoelectric conversion device shown in FIG. 6.

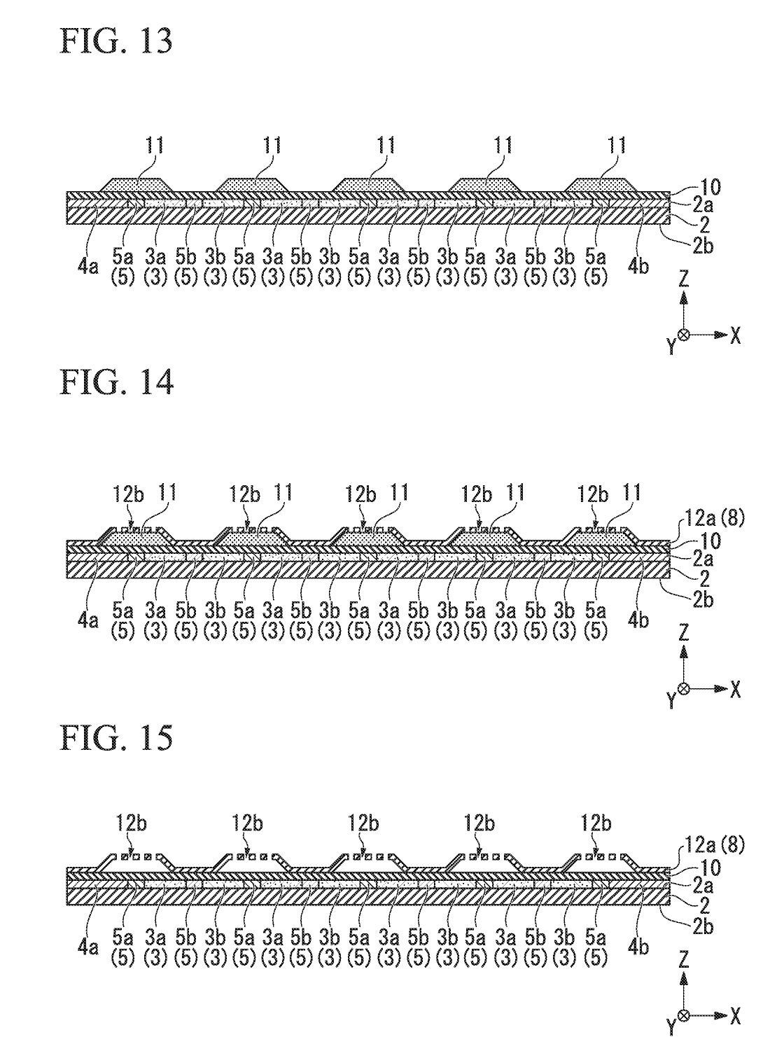

FIG. 13 is a cross-sectional view for sequentially explaining a manufacturing process of the thermoelectric conversion device shown in FIG. 6.

FIG. 14 is a cross-sectional view for sequentially explaining a manufacturing process of the thermoelectric conversion device shown in FIG. 6.

FIG. 15 is a cross-sectional view for sequentially explaining a manufacturing process of the thermoelectric conversion device shown in FIG. 6.

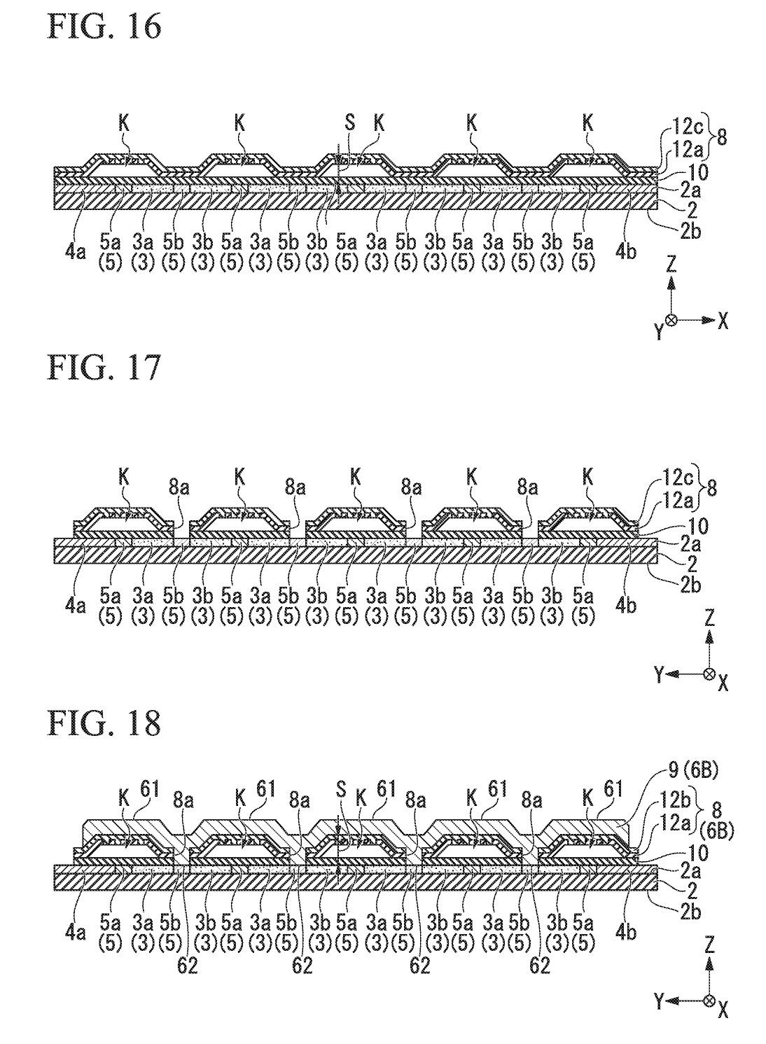

FIG. 16 is a cross-sectional view for sequentially explaining a manufacturing process of the thermoelectric conversion device shown in FIG. 6.

FIG. 17 is a cross-sectional view for sequentially explaining a manufacturing process of the thermoelectric conversion device shown in FIG. 6.

FIG. 18 is a cross-sectional view for sequentially explaining the manufacturing process of the thermoelectric conversion device shown in FIG. 6.

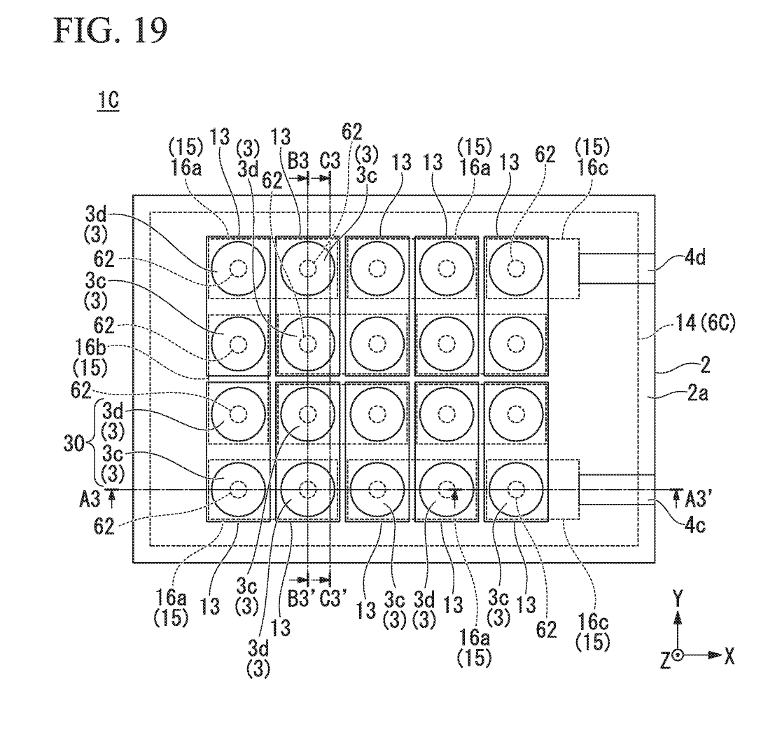

FIG. 19 is a transparent plan view showing a schematic configuration of a thermoelectric conversion device according to a third embodiment of the present disclosure.

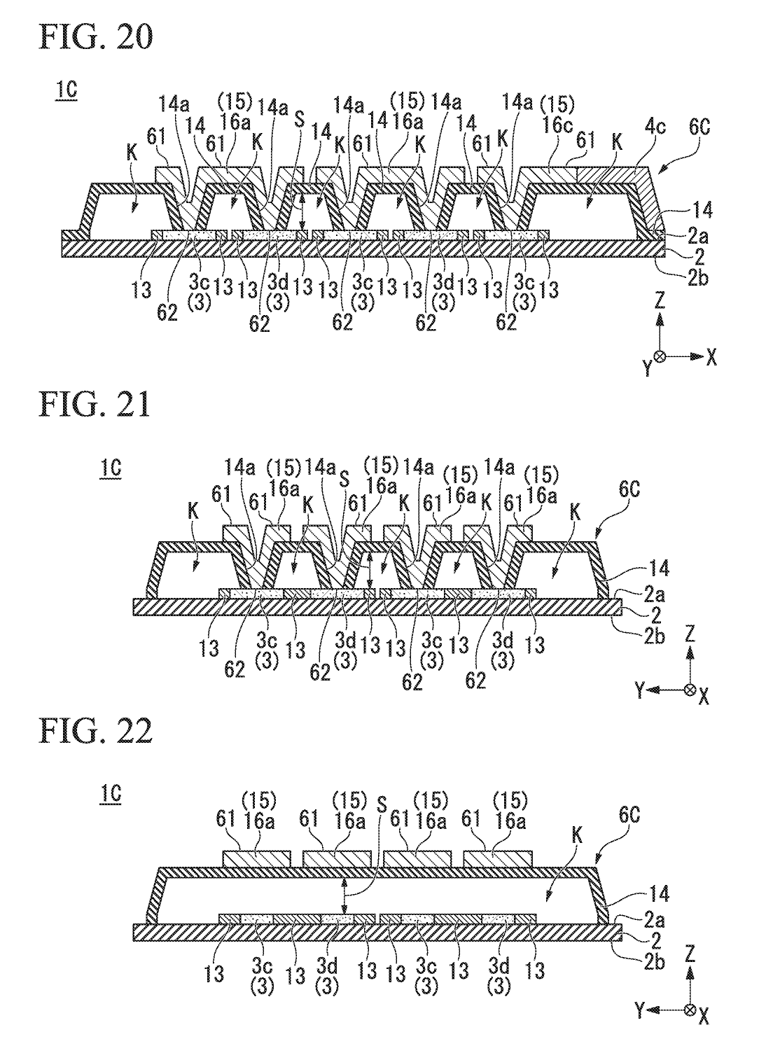

FIG. 20 is a cross-sectional view of the thermoelectric conversion device according to the line segment A3-A3′ shown in FIG. 19.

FIG. 21 is a cross-sectional view of the thermoelectric conversion device according to the line segment B3-B3′ shown in FIG. 19.

FIG. 22 is a cross-sectional view of the thermoelectric conversion device according to the line segment C3-C3′ shown in FIG. 19.

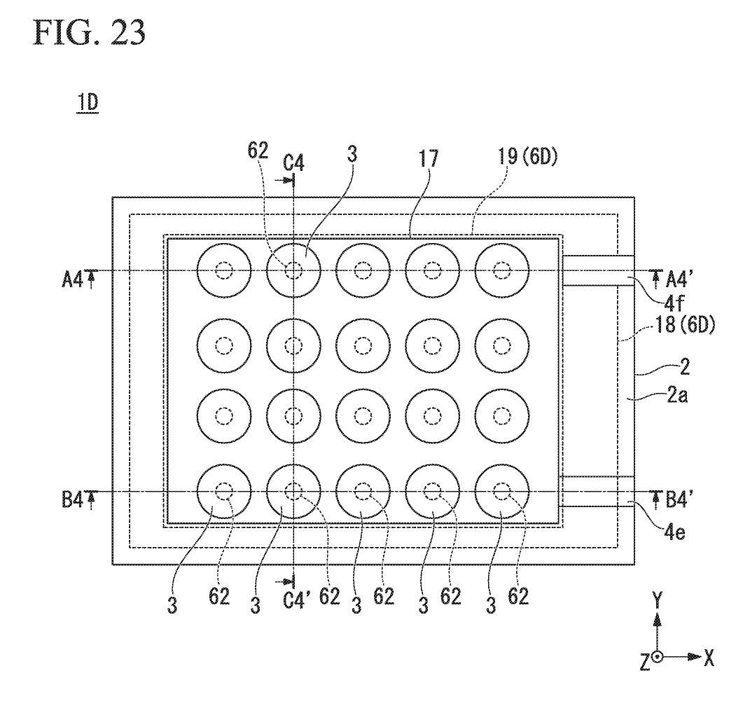

FIG. 23 is a transparent plan view showing a schematic configuration of a thermoelectric conversion device according to a fourth embodiment of the present disclosure.

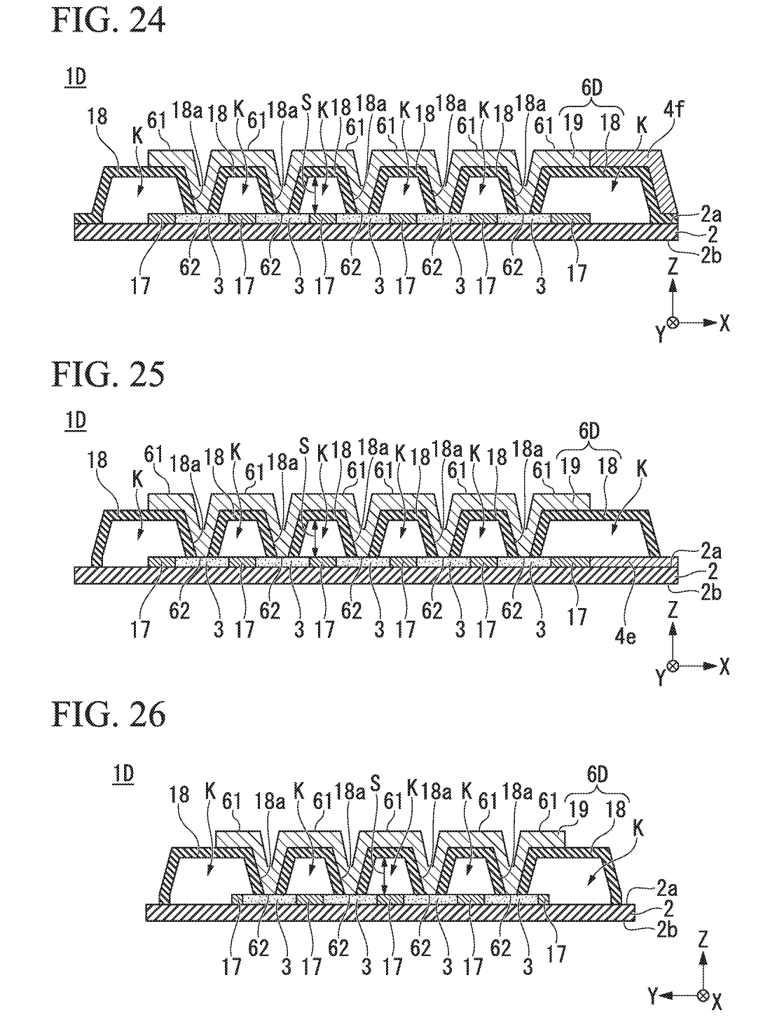

FIG. 24 is a cross-sectional view of the thermoelectric conversion device according to the line segment A4-A4′ shown in FIG. 23.

FIG. 25 is a cross-sectional view of the thermoelectric conversion device according to the line segment B4-B4′ shown in FIG. 23.

FIG. 26 is a cross-sectional view of a thermoelectric conversion device according to the line segment C4-C4′ shown in FIG. 23.

### DETAILED DESCRIPTION

Hereinafter, embodiments of the present disclosure will be described in detail with reference to the figures.

In the figures used in the following description, for the sake of easy understanding of the features, characteristic portions may be shown enlarged for convenience, and dimensional proportions or the like for each component may not be the same as those in actuality. Also, materials or the like exemplified in the following description are merely examples, and the present invention is not necessarily limited thereto and can be carried out with appropriate modifications within the gist thereof.

### First Embodiment

First, as a first embodiment of the present disclosure, for example, a thermoelectric conversion device 1A shown in FIGS. 1 to 5 will be described. FIG. 1 is a transparent plan view showing a schematic configuration of the thermoelectric conversion device 1A. FIG. 2 is a cross-sectional view of the thermoelectric conversion device 1A according to the line segment A1-A1′ shown in FIG. 1. FIG. 3 is a cross-sectional view of the thermoelectric conversion device 1A according to the line segment B1-B1′ shown in FIG. 1. FIG. 4 is a cross-sectional view of the thermoelectric conversion device 1A according to the line segment C1-C1′ shown in FIG. 1. FIG. 5 is an enlarged cross-sectional view of a portion of the thermoelectric conversion device 1A shown in FIG. 2.

Also, in the following figures, an XYZ orthogonal coordinate system is set, in which an X-axis direction is defined as a first direction in a specific plane of the thermoelectric conversion device 1A, a Y-axis direction is defined as a second direction in the specific plane of the thermoelectric conversion device 1A, and a Z-axis direction is shown as a thickness direction (a height direction) orthogonal to the specific plane of the thermoelectric conversion device 1A.

As shown in FIGS. 1 to 5, the thermoelectric conversion device 1A of the present embodiment has a configuration in which a plurality of (eight in the present embodiment) thermoelectric conversion elements 3 disposed side by side on a surface of a substrate 2 are connected in series with each other between a pair of terminals 4a and 4b.

The substrate 2 is made of an insulating base material having a first surface (an upper surface in this embodiment) 2a and a second surface (a lower surface in this embodiment) 2b that face each other in the thickness direction. It is preferable to use, for example, a high resistance silicon (Si) substrate having a sheet resistance of 10Ω or more as the substrate 2. By setting the sheet resistance of the substrate 2 to 10Ω or more, it is possible to prevent electrical short-circuiting between the plurality of thermoelectric conversion elements 3.

Also, as the substrate 2, in addition to the above-described high resistance Si substrate, for example, a silicon on insulator (SOI) substrate having an oxide insulating layer in the substrate, a ceramic substrate, a glass substrate, another high resistance single crystal substrate, or the like can be used. Further, as the substrate 2, a substrate having a sheet resistance of 10Ω or less may be used, or a substrate having a high resistance material disposed between the low resistance substrate and the thermoelectric conversion element 3 may be used.

The plurality of thermoelectric conversion elements 3 are disposed in parallel at regular intervals in the first direction such that among the first direction and the second direction crossing each other (orthogonal to each other in the present embodiment) in a plane on the first surface 2a side (in a specific plane) of the substrate 2, the first direction is set to be a longitudinal direction thereof and the second direction is set to be a lateral direction thereof. Also, each of thermoelectric conversion elements 3 is formed in the same size and in an oblong shape (a rectangular shape in the present embodiment) in a plan view.

The plurality of thermoelectric conversion elements 3 include a first thermoelectric conversion element (one thermoelectric conversion element) 3a made of either of a p-type semiconductor or an n-type semiconductor (the n-type semiconductor in this embodiment), and a second thermoelectric conversion element (other thermoelectric conversion element) 3b made of the other of the p-type semiconductor or the n-type semiconductor (the p-type semiconductor in the present embodiment) alternately disposed in a row.

In the first thermoelectric conversion element 3a, for example, a multilayer film including an n-type silicon (Si) film and an n-type silicon-germanium (SiGe) alloy film both doped with antimony (Sb) at a high concentration (10¹⁸ to 10¹⁹ cm⁻³) can be used. In the first thermoelectric conversion element 3a made of the n-type semiconductor, a current flows from a cold junction side to a hot junction side.

In the second thermoelectric conversion element 3b, for example, a multilayer film including a p-type silicon (Si) film and a p-type silicon-germanium (SiGe) alloy film both doped with boron (B) at a high concentration (10¹⁸ to 10¹⁹ cm⁻³) can be used. In the second thermoelectric conversion element 3b made of the p-type semiconductor, a current flows from the hot junction side to the cold junction side.

In addition, the thermoelectric conversion element 3 is not necessarily limited to a multilayer film of a p-type or n-type semiconductor as described above, and may be a single layer film of a p-type or n-type semiconductor. Also, an oxide-based semiconductor can be used as a semiconductor. Also, a thermoelectric conversion film made of an organic polymer film, a metal film, or the like can be used. Also, the thermoelectric conversion element 3 is not limited to the above-described thermoelectric conversion film, and a bulk one may be used.

The thermoelectric conversion device 1A of the present embodiment includes a plurality of (nine in this embodiment) electrodes 5 provided side by side in an arrangement direction (first direction) in which the plurality of thermoelectric conversion elements 3 are arranged. The plurality of thermoelectric conversion elements 3 are disposed between the first electrodes 5a and the second electrodes 5b which are alternately adjacent to each other in the arrangement direction of the plurality of electrodes 5, and are electrically connected to the first electrode 5a and the second electrode 5b.

The plurality of electrodes 5 are formed in the same size and in an oblong shape (a rectangular shape in the present embodiment) in a plan view over the entire area in the longitudinal direction (the second direction) of the thermoelectric conversion element 3 in contact with side surfaces on one end side and side surfaces on the other end side which oppose each other in the first direction of the thermoelectric conversion element 3. For the electrode 5, for example, copper (Cu), gold (Au), or the like, which has high electrical conductivity and thermal conductivity and is easily shaped, can be suitably used.

The plurality of electrodes 5 are configured with five first electrodes 5a which are cold junction side electrodes and four second electrodes 5b which are hot junction side electrodes alternately arranged in parallel. The first electrodes 5a are disposed on one end side (−X side in the present embodiment) of each first thermoelectric conversion element 3a and one end side (+X side in the present embodiment) of each second thermoelectric conversion element 3b. On the other hand, the second electrodes 5b are disposed on other end side (+X side in the present embodiment) of each first thermoelectric conversion element 3a and other end side (−X side in the present embodiment) of each second thermoelectric conversion element 3b. That is, in the thermoelectric conversion device 1A of the present embodiment, one end side of each first thermoelectric conversion element 3a is on the −X side and other end side of each first thermoelectric conversion element 3a is on the +X side. On the other hand, one end side of each second thermoelectric conversion element 3b is on the +X side and the other end side of each second thermoelectric conversion element 3b is on the −X side.

In the first thermoelectric conversion element 3a made of an n-type semiconductor, a current flows from the first electrode 5a side serving as a cold junction to the second electrode 5b side serving as a hot junction. On the other hand, in the second thermoelectric conversion element 3b made of a p-type semiconductor, a current flows from the second electrode 5b side serving as the hot junction to the first electrode 5a side serving as the cold junction.

Therefore, in the thermoelectric conversion device 1A of the present embodiment, the direction of the current flowing through the first thermoelectric conversion element 3a and the direction of the current flowing through the second thermoelectric conversion element 3b are the same direction.

One terminal 4a of the pair of terminals 4a and 4b is electrically connected to the first electrode 5a disposed on the −X side of the thermoelectric conversion element 3 (in the present embodiment, the first thermoelectric conversion element 3a) positioned on the one endmost side (−X side) in the arrangement direction of the thermoelectric conversion elements 3. On the other hand, other terminal 4b is electrically connected to the first electrode 5a disposed on the +X side of the thermoelectric conversion element 3 (in the present embodiment, the second thermoelectric conversion element 3b) positioned on other endmost side (+X side) in the arrangement direction of the thermoelectric conversion elements 3. Also, for the pair of terminals 4a and 4b, the same material as that of the electrode 5 may be used.

The thermoelectric conversion device 1A of the present embodiment includes a heat transfer part 6A thermally connected to the plurality of thermoelectric conversion elements 3. The heat transfer part 6A is made of a material having a thermal conductivity higher than that of air, preferably a material having a thermal conductivity higher than that of the substrate 2. As a material of such a heat transfer part 6A, a metal, and among them, in particular, aluminum (Al), copper (Cu) or the like which has high thermal conductivity and is easily shaped, can be suitably used. Also, for a material of the heat transfer part 6A, a ceramic material such as aluminum oxide (Al₂O₃) can also be used. Further, the heat transfer part 6A may include a plurality of members.

The heat transfer part 6A has a separation portion 61 which is disposed with a gap S between itself and each of the thermoelectric conversion element 3 and the first electrode 5a while facing the first surface 2a side of the substrate 2, and a plurality of (four in the present embodiment) heat transfer portions 62 which protrude toward a side facing each of the thermoelectric conversion elements 3 in a state where a portion thereof opposite to the side facing each of the thermoelectric conversion elements 3 is recessed.

The separation portion 61 is positioned between neighboring heat transfer portions 62 and is separated from each of the thermoelectric conversion elements 3 and the first electrode 5a to form a space K corresponding to the gap S therebetween. The plurality of heat transfer portions 62 protrude to include a region overlapping each second electrode 5b in a plan view in accordance with each of the second electrodes 5b, whereby respective tips thereof abut the respective second electrodes 5b. As a result, the heat transfer part 6A is thermally connected to other end side (the hot junction side) of the thermoelectric conversion element 3 through the heat transfer portion 62 abutting the second electrode.

In addition, the respective tips of the heat transfer portions 62 are thermally connected to each of the second electrodes 5b in a state in which they are electrically insulated from the respective second electrodes 5b via an insulating layer (not shown). As a result, the gap S is provided between the heat transfer portions 62 adjacent to each other.

For the insulating layer, as one constituting a portion of the heat transfer portion 62, for example, an insulating material having thermal conductivity higher than that of air such as aluminum oxide (Al₂O₃), silicon oxide (SiO₂), silicon nitride (SiN), aluminum nitride (AlN), or the like can be used. Also, for the insulating layer, for example, a UV-curable resin, a silicone-based resin, a thermal conductive grease (for example, a silicone-based grease, a non-silicone-based grease containing a metal oxide, etc.) or the like can be used. Also, in the case where the electrical insulation between the tip of the heat transfer portion 62 and the second electrode 5b does not matter, the tip of the heat transfer portion 62 and the second electrode 5b may be directly connected to each other without providing the insulating layer mentioned above.

In the thermoelectric conversion device 1A of the present embodiment, a space between the substrate 2 and the heat transfer part 6A is sealed via a sealing material 7 at an outside of peripheries of the plurality of thermoelectric conversion elements 3. The sealing material 7 is made of, for example, a high-temperature resistant adhesive such as a silicone-based adhesive and the like, and surrounds and seals the periphery between the substrate 2 and the heat transfer part 6A. The pair of terminals 4a and 4b are provided to be drawn from the inside sealed with this sealing material 7 to the outside.

In addition, a decompressed space K is provided between the substrate 2 and the heat transfer part 6A sealed by the sealing material 7. Thus, the thermoelectric conversion device 1A has the decompressed space K in the space between each thermoelectric conversion element 3 and the first electrode 5a and the separation portion 61 (at a position corresponding to the gap S). In the thermoelectric conversion device 1A of the present embodiment, it is also possible to adopt a configuration in which the space K is filled with a low thermal conductive material (including air) having a thermal conductivity lower than that of the heat transfer portion 62.

In the thermoelectric conversion device 1A of the present embodiment having the configuration described above, the heat transfer part 6A is disposed on the high temperature (heat source) side and the substrate 2 is disposed on the low temperature (heat-radiating/cooling) side. Thus, since the heat H (see the solid arrow in FIG. 5) transferred from the heat source W (for example, a fluid such as a liquid or gas having heat) to the heat transfer part 6A is transferred through the heat transfer portion 62 to the second electrode 5b, the second electrode 5b side of each thermoelectric conversion element 3 becomes relatively higher in temperature than the first electrode 5a side, whereby a temperature difference occurs between the first electrode 5a and the second electrode 5b of each thermoelectric conversion element 3.

As a result, movement of electric charge (carriers) occurs between the first electrode 5a and the second electrode 5b of each thermoelectric conversion element 3. That is, an electromotive force (voltage) due to the Seebeck effect is generated between the first electrode 5a and the second electrode 5b of each thermoelectric conversion element 3.

Here, although the electromotive force (voltage) generated in one thermoelectric conversion element 3 is small, the first thermoelectric conversion element 3a and the second thermoelectric conversion element 3b are alternately connected in series between one terminal 4a and other terminal 4b. Therefore, a relatively high voltage can be taken out as a sum of the electromotive forces between the one terminal 4a and the other terminal 4b.

In the thermoelectric conversion device 1A of the present embodiment, the heat transfer part 6A and the thermoelectric conversion element 3 are thermally connected to each other via the heat transfer portion 62 which protrudes toward the side facing the thermoelectric conversion element 3 in a state in which a portion of a side opposite to the side facing the at least one thermoelectric conversion element 3 described above is recessed. On the other hand, the separation portion 61 of the heat transfer part 6A is disposed with a gap S between itself and each thermoelectric conversion element 3 and the first electrode 5a.

In this configuration, as schematically shown in FIG. 5, the heat source W is disposed on a surface (hereinafter referred to as a heat receiving surface T) side of the heat transfer part 6A opposite to the side facing the thermoelectric conversion element 3. At this time, in the heat transfer portion 62, the distance in the thickness direction from the heat receiving surface T to the second electrode 5b serving as the hot junction of the thermoelectric conversion element 3 becomes relatively short, and the heat H transferred from the heat source W to the heat transfer part 6A is easily transferred to the second electrode 5b side (see the broken line arrow in FIG. 5).

On the other hand, in the separation portion 61, the distance in the thickness direction from the heat receiving surface T to the first electrode 5a serving as the cold junction of the thermoelectric conversion element 3 becomes relatively long, and the heat H is not as easily transferred from the heat source W to the heat transfer part 6A to be transferred to the first electrode 5a side (see the broken line arrow shown in FIG. 5). Thus, it is possible to obtain a high output by obtaining a large temperature difference between the hot junction and the cold junction of each thermoelectric conversion element 3.

Further, in the thermoelectric conversion device 1A of the present embodiment, the decompressed space K is provided between the above-described heat transfer part 6A and each thermoelectric conversion element 3 and the first electrode 5a. This space K has a function of blocking (heat-insulating) the heat H, which is transferred from the heat source W to the heat transfer part 6A, between each thermoelectric conversion element 3 and the first electrode 5a and the separation portion 61. Since this makes it difficult for the heat H transferred from the heat source W to the heat transfer part 6A to be transferred further to the first electrode 5a side in the separation portion 61, the temperature difference between the hot junction and the cold junction of each thermoelectric conversion element 3 increases, and even higher output can be obtained.

As described above, in the thermoelectric conversion device 1A of the present embodiment, the heat H transferred from the heat source W to the heat transfer part 6A can be efficiently transferred to the hot junction side of the thermoelectric conversion element 3, and it is possible to improve the thermoelectric conversion characteristic of the thermoelectric conversion device 1A.

### Second Embodiment

Next, as a second embodiment of the present disclosure, a thermoelectric conversion device 1B shown in FIGS. 6 to 9 will be described, for example. FIG. 6 is a transparent plan view showing a schematic configuration of the thermoelectric conversion device 1B. FIG. 7 is a cross-sectional view of the thermoelectric conversion device 1B according to the line segment A2-A2′ shown in FIG. 6. FIG. 8 is a cross-sectional view of the thermoelectric conversion device 1B according to the line segment B2-B2′ shown in FIG. 6. FIG. 9 is a cross-sectional view of the thermoelectric conversion device 1B according to the line segment C2-C2′ shown in FIG. 6. In the following description, explanations for the same components as those of the thermoelectric conversion device 1A will be omitted and the same reference numerals therefor will be used in the figures.

As shown in FIGS. 6 to 9, in place of the heat transfer part 6A included in the thermoelectric conversion device 1A, the thermoelectric conversion device 1B according to the present embodiment includes a heat transfer part 6B in which a plurality of (two in the present embodiment) heat transfer layers 8 and 9 are stacked. In addition, on the first surface 2a side of the substrate 2, a protective layer 10 which covers at least the surfaces of the respective thermoelectric conversion elements 3 and first electrodes 5a except for the surfaces of the respective second electrodes 5b is provided.

The heat transfer part 6B has a structure in which the first heat transfer layer 8 and the second heat transfer layer 9 are stacked in this order. Among them, a material having higher thermal conductivity than air such as aluminum oxide (Al₂O₃), silicon oxide (SiO₂), silicon nitride (SiN), or the like is used for the first heat transfer layer 8. On the other hand, a metal material such as aluminum (Al) or copper (Cu) is used for the second heat transfer layer 9 as a material having a thermal conductivity higher than a thermal conductivity of the first heat transfer layer 8. Similarly to the first heat transfer layer 8, an insulating material such as aluminum oxide (Al₂O₃), silicon oxide (SiO₂), silicon nitride (SiN), or the like is used for the protective layer 10.

The first heat transfer layer 8 has an opening portion 8a at a position corresponding to each second electrode 5b and a periphery of the opening portion 8a abuts the protective layer 10 while being inclined toward the substrate 2. Thus, a portion of the first heat transfer layer 8 is disposed as a separation portion 61 with a gap S between itself and each of the thermoelectric conversion element 3 and the first electrode 5a. Therefore, in the separation portion 61, the first heat transfer layer 8 is positioned closer to the thermoelectric conversion element 3 side than the second heat transfer layer 9.

In addition, at an outside of peripheries of the plurality of thermoelectric conversion elements 3, an outer peripheral portion of the first heat transfer layer 8 abuts the protective layer 10 while being inclined toward the substrate 2 side. In this way, a space between the substrate 2 and the first heat transfer layer 8 (the heat transfer part 6B) is sealed.

Further, a decompressed space K is provided between the sealed substrate 2 and the first heat transfer layer 8 (the heat transfer part 6B). As a result, the thermoelectric conversion device 1B has the decompressed space K in a space (at a position corresponding to the gap S) between each of the thermoelectric conversion elements 3 and the first electrode 5a and the first heat transfer layer 8 (the separation portion 61).

The second heat transfer layer 9 covers a surface of the first heat transfer layer 8 and abuts each second electrode 5b through the opening portion 8a. Thus, the second heat transfer layer 9 forms a portion of the separation portion 61 at a position covering the surface of the first heat transfer layer 8 (a position corresponding to the gap S). Also, a portion of the second heat transfer layer 9 forms a plurality of heat transfer portions 62 which protrude toward the side facing each thermoelectric conversion element 3 in a state where a portion thereof on a side opposite to the side facing each thermoelectric conversion element 3 is recessed. In addition, respective tips of the heat transfer portions 62 are thermally connected to the respective second electrodes 5b in a state in which the tips are electrically insulated from the respective second electrodes 5b via an insulating layer (not shown).

In the thermoelectric conversion device 1B of the present embodiment having the configuration described above, the second heat transfer layer 9 (the heat transfer part 6B) and the thermoelectric conversion element 3 are thermally connected via the heat transfer portion 62 which protrudes toward the side facing the thermoelectric conversion element 3 in a state where a portion thereof on the side opposite to the side facing the thermoelectric conversion element 3 described above is recessed. On the other hand, a portion of the first heat transfer layer 8 is disposed as the separation portion 61 with the gap S between itself and each of the thermoelectric conversion element 3 and the first electrode 5a.

In this configuration, the heat source W is disposed on a surface (heat receiving surface T) side of the heat transfer part 6B opposite to the side facing thermoelectric conversion element 3. Also, in FIGS. 6 to 9, illustration of the heat receiving surface T and the heat source W is omitted. At this time, in the heat transfer portion 62, the distance in the thickness direction from the heat receiving surface T to the second electrode 5b serving as the hot junction of the thermoelectric conversion element 3 becomes relatively short, so that the heat H transferred from the heat source W to the heat transfer part 6B is easily transferred to the second electrode 5b side.

On the other hand, in the separation portion 61, since the distance in the thickness direction from the heat receiving surface T to the first electrode 5a serving as the cold junction of the thermoelectric conversion element 3 is relatively long, the heat H transferred from the heat source W to the heat transfer part 6B is not easily transferred to the side of the first electrode 5a. Thus, it is possible to obtain a high output by obtaining a large temperature difference between the hot junction and the cold junction of each thermoelectric conversion element 3.

Further, in the thermoelectric conversion device 1B of the present embodiment, the heat transfer portion 62 is formed by the second heat transfer layer 9 having a thermal conductivity higher than that of the above-described first heat transfer layer 8, and the separation portion 61 is formed by the first heat transfer layer 8 having a thermal conductivity lower than that of the second heat transfer layer 9. In this configuration, it is possible to efficiently transfer the heat H transferred from the heat source W to the heat transfer part 6B to the second electrode 5b side serving as the hot junction.

Further, in the thermoelectric conversion device 1B of the present embodiment, the decompressed space K is provided between the above-described first heat transfer layer 8 (the heat transfer part 6B) and each thermoelectric conversion element 3 and first electrode 5a. This space K has a function of blocking (heat-insulating) the heat H, which is transferred from the heat source W to the heat transfer part 6B, between each of the thermoelectric conversion elements 3 and the first electrode 5a and the first heat transfer layer 8 (the separation portion 61). As a result, in the separation portion 61, since the heat H transferred from the heat source W to the heat transfer part 6B is not easily further transferred to the first electrode 5a side, it is possible to increase the temperature difference between the hot junction and the cold junction of each thermoelectric conversion element 3, and even higher output can be obtained.

As described above, in the thermoelectric conversion device 1B of the present embodiment, similarly to the thermoelectric conversion device 1A, it is possible to efficiently transfer the heat H transferred from the heat source W to the heat transfer part 6B to the hot junction side of the thermoelectric conversion element 3 and it is possible to improve the thermoelectric conversion characteristics of the thermoelectric conversion device 1B.

Next, a method of manufacturing the thermoelectric conversion device 1B will be described with reference to FIGS. 10 to 18. FIGS. 10 to 18 are cross-sectional views corresponding to the line segment A2-A2′ shown in FIG. 6 for sequentially explaining a manufacturing process of the thermoelectric conversion device 1B.

When manufacturing the thermoelectric conversion device 1B, in the chamber in which the inside is decompressed, first, as shown in FIG. 10, an n-type thermoelectric conversion film which becomes the first thermoelectric conversion elements 3a is formed on the first surface 2a of the substrate 2, and then the n-type thermoelectric conversion film is selectively removed by pattern etching using a photoresist. Thus, a plurality of first thermoelectric conversion elements 3a arranged at regular intervals in the first direction are formed. Similarly, a p-type thermoelectric conversion film which becomes the second thermoelectric conversion elements 3b is formed on the first surface 2a of the substrate 2, and then the p-type thermoelectric conversion film is selectively removed by pattern etching using a photoresist. Thus, a plurality of second thermoelectric conversion elements 3b arranged at regular intervals in the first direction are formed between each of the plurality of first thermoelectric conversion elements 3a.

Next, as shown in FIG. 11, after a conductive base film is formed on the first surface 2a of the substrate 2, a resist mask having opening portions is formed at positions corresponding to a pair of terminals 4a and 4b and a plurality of electrodes 5 using a photoresist. After a conductive film is formed by electrolytic plating, the resist mask and the conductive base film on each thermoelectric conversion film are removed. As a result, the pair of terminals 4a and 4b and the plurality of electrodes 5 (the first electrode 5a and the second electrode 5b) are formed.

Next, as shown in FIG. 12, a protective layer 10 is formed to cover the surface on which the plurality of thermoelectric conversion elements 3, the pair of terminals 4a and 4b, and the plurality of electrodes 5 are formed.

Next, as shown in FIG. 13, a silicon (Si) film is formed on the surface of the protective layer 10 by, for example, a chemical vapor deposition (CVD) method, and then, a resist mask is formed at a position corresponding to the gap S (the space K) using a photoresist. Then, after the Si film is selectively removed by dry etching using reactive ion etching (RIE), the resist mask is removed. As a result, a sacrificial layer 11 corresponding to the gap S (the space K) is formed.

Next, as shown in FIG. 14, after forming a first covering layer 12a covering the surface on which the sacrificial layer 11 is formed, the first covering layer 12a is selectively removed by pattern etching using a photoresist. Thus, the first covering layer 12a having a plurality of opening portions 8b is formed on the surface of the sacrificial layer 11. The first covering layer 12a is formed by a CVD method or a sputtering method using the material for the first heat transfer layer 8 described above. In addition, a plurality of opening portions 12b are formed in the first covering layer 12a by dry etching using reactive ion etching (RIE).

Next, as shown in FIG. 15, the sacrificial layer 11 is removed through the plurality of opening portions 12b by dry etching using reactive ion etching (RIE).

Next, as shown in FIG. 16, a second covering layer 12c covering the surface on which the first covering layer 12a is formed is formed. The second covering layer 12c is formed by a CVD method or a sputtering method using the material for the first heat transfer layer 8 described above. Thus, the plurality of opening portions 12b are in a state of being closed by the second covering layer 12c, and the first heat transfer layer 8 including the first covering layer 12a and the second covering layer 12c is formed. Further, the space K corresponding to the gap S is formed between the first heat transfer layer 8 and the protective layer 10.

Next, as shown in FIG. 17, a resist mask having opening portions at positions corresponding to the respective second electrodes 5b is formed using a photoresist. Then, the first covering layer 12a and the second covering layer 12c are selectively removed by dry etching using reactive ion etching (RIE), and then the resist mask is removed. As a result, the opening portion 8a is formed at a position corresponding to each second electrode 5b of the first heat transfer layer 8.

Next, as shown in FIG. 18, after a conductive base film is formed on the surface on which the first heat transfer layer 8 is formed, using a photoresist, a resist mask having opening portions at positions corresponding to the second heat transfer layer 9 is formed. After a metal film is formed by electrolytic plating, the resist mask is removed. Thus, the second heat transfer layer 9 including the separation portion 61 which is disposed with a gap S between itself and each of the thermoelectric conversion element 3 and the first electrode 5a and a plurality of heat transfer portions 62 which abuts each second electrode 5b through the opening portions 8a is formed, and then the resist mask is removed.

According to the present embodiment, by forming the heat transfer part 6B in the chamber in which the inside thereof is depressurized as described above, it is possible to form the decompressed space K in the space (the region corresponding to the gap S) between each of the thermoelectric conversion element 3 and the first electrode 5a and the heat transfer part 6B formed by the first heat transfer layer 8 and the second heat transfer layer 9.

Also, in the process shown in FIG. 17, in order that the tip of the heat transfer portion 62 formed by the second heat transfer layer 9 abuts the second electrode 5b in a state of being electrically insulated, it is also possible to leave a portion of the protective layer 10 as the insulating layer at the positions where the opening portions 8a are formed.

### Third Embodiment

Next, as a third embodiment of the present disclosure, a thermoelectric conversion device 1C shown in FIGS. 19 to 22 will be described, for example. FIG. 19 is a transparent plan view showing a schematic configuration of the thermoelectric conversion device 1C. FIG. 20 is a cross-sectional view of the thermoelectric conversion device 1C according to the line segment A3-A3′ shown in FIG. 19. FIG. 21 is a cross-sectional view of the thermoelectric conversion device 1C according to line segment B3-B3′ shown in FIG. 19. FIG. 22 is a cross-sectional view of the thermoelectric conversion device 1C according to the line segment C3-C3′ shown in FIG. 19. In the following description, explanations for the same components as those of the thermoelectric conversion device 1A will be omitted and the same reference numerals therefor will be used in the figures.

As shown in FIGS. 19 to 22, a thermoelectric conversion device 1C according to the present embodiment has a structure in which a plurality of (twenty in this embodiment) thermoelectric conversion elements 3 arranged in parallel on the surface of the substrate 2 are connected in series with a pair of terminals 4c and 4d.

A plurality of thermoelectric conversion elements 3 are juxtaposed in the first direction and the second direction crossing each other (orthogonal to each other in the present embodiment) in a plane on the first surface 2a side (in a specific plane) of the substrate 2. In the present embodiment, five thermoelectric conversion elements 3 are provided in the first direction and four thermoelectric conversion elements 3 are provided in the second direction. In addition, each thermoelectric conversion element 3 is formed in a circular shape having the same size in a plan view.

The plurality of thermoelectric conversion elements 3 are configured such that a first thermoelectric conversion element (one thermoelectric conversion element) 3c made of either of a p-type semiconductor or an n-type semiconductor (the n-type semiconductor in this embodiment) and a second thermoelectric conversion element (other thermoelectric conversion element) 3d made of the other of the p-type semiconductor or the n-type semiconductor (the p-type semiconductor in the present embodiment) are alternately arranged in parallel in the first direction and the second direction. Also, the first thermoelectric conversion element 3c can be the same as the first thermoelectric conversion element 3a described above, and the first thermoelectric conversion element 3c can be the same as the second thermoelectric conversion element 3b described above.

The thermoelectric conversion device 1C of the present embodiment incudes a plurality of (ten in the present embodiment) lower electrodes (edge electrodes) 13 which electrically connect the first thermoelectric conversion elements 3c and the second thermoelectric conversion elements 3d adjacent to each other in the second direction among the plurality of thermoelectric conversion elements 3.

Each lower electrode 13 is formed to surround the first and second thermoelectric conversion elements 3c and 3d which are adjacent in the second direction in contact with outer periphery portions of the first thermoelectric conversion element 3c and the second thermoelectric conversion element 3d. In addition, each of the lower electrodes 13 is formed to have the same size and outer contour in an oblong shape (a rectangular shape in the present embodiment) in a plan view. For the lower electrode 13, an electrode the same as the electrode 5 can be used.

The thermoelectric conversion device 1C of the present embodiment includes a heat transfer part 6C thermally connected to the plurality of thermoelectric conversion elements 3. The heat transfer part 6C has a structure in which a first heat transfer layer 14 and a plurality of (eleven in the present embodiment) second heat transfer layers 15 are stacked in this order. Among them, one the same as the first heat transfer layer 8 may be used for the first heat transfer layer 14, and one the same as the second heat transfer layer 9 may be used for the second heat transfer layer 15.

That is, in the heat transfer part 6C of the present embodiment, the second heat transfer layer 15 has a thermal conductivity higher than a thermal conductivity of the first heat transfer layer 14. In addition, the first heat transfer layer 14 has insulating properties, and the second heat transfer layer 15 has electrical conductivity.

The first heat transfer layer 14 has an opening portion 14a at a position corresponding to a center portion of each thermoelectric conversion element 3, and peripheries of the opening portion 14a is inclined toward the substrate 2 and abuts the thermoelectric conversion element 3. Thus, a portion of the first heat transfer layer 14 is disposed as a separation portion 61 with a gap S between itself and a portion of each thermoelectric conversion element 3 and the lower electrode 13.

In addition, at an outside of the peripheries of the plurality of thermoelectric conversion elements 3, an outer peripheral portion of the first heat transfer layer 14 abuts the first surface 2a while being inclined toward the substrate 2. Thus, a space between the substrate 2 and the first heat transfer layer 14 (the heat transfer part 6C) is sealed.

Further, a decompressed space K is provided between the sealed substrate 2 and the first heat transfer layer 14 (the heat transfer part 6). Thus, the thermoelectric conversion device 1C has the decompressed space K (the position corresponding to the gap S) between a portion of the thermoelectric conversion element 3 and the lower electrode 13 and the first heat transfer layer 14 (the separation portion 61).

The plurality of second heat transfer layers 15 are disposed on the surface of the first heat transfer layer 14 and abut the vicinity of the center of each thermoelectric conversion element 3 through each opening portion 14a. Thus, the second heat transfer layer 15 forms a portion of the separation portion 61 at a position covering the surface of the first heat transfer layer 14 (the position corresponding to the gap S). Also, a portion of the second heat transfer layer 15 forms a plurality of heat transfer portions 62 which protrude toward a side facing each thermoelectric conversion element 3 in a state where a portion thereof on a side opposite to the side facing each thermoelectric conversion element 3 is recessed. Also, the second heat transfer layer 15 (the heat transfer part 6C) is thermally connected to the vicinity of the center of the thermoelectric conversion element 3 via the heat transfer portion 62.

In addition, the plurality of second heat transfer layers 15 constitutes an upper electrode (center electrode) which electrically connects cells 30 which are adjacent to each other via the heat transfer portion 62, with the first thermoelectric conversion element 3c and the second thermoelectric conversion element 3d electrically connected via the lower electrode 13 serving as one cell 30.

Specifically, among the plurality of second heat transfer layers 15, eight second heat transfer layers 15 constitute a first upper electrode 16a which electrically connects the first thermoelectric conversion element 3c and the second thermoelectric conversion element 3d of a plurality of (in this embodiment, five) cells 30 adjacent to each other in the first direction in an alternate manner (in a staggered manner).

On the other hand, one second heat transfer layer 15 constitutes a second upper electrode 16b which is positioned on one endmost side (−X side) in the first direction among the cells 30 adjacent to each other in the second direction, and electrically connects between the first thermoelectric conversion element 3c and the second thermoelectric conversion element 3d of the adjacent cells 30.

On the other hand, two second heat transfer layers 15 constitute a third upper electrode 16c which is positioned on other endmost side (+X side) in the first direction among the cells 30 adjacent to each other in the second direction, and are electrically connected to either of the first thermoelectric conversion element 3c or the second thermoelectric conversion element 3d of the adjacent cells 30.

The first, second, and third upper electrodes 16a, 16b and 16c (the second heat transfer layer 15) are formed in an oblong shape (a rectangular shape in the present embodiment) in a plan view in each direction. Further, each of the upper electrodes 16a, 16b and 16c is electrically connected to the vicinity of the center of each thermoelectric conversion element 3 via the heat transfer portion 62.

Thus, the thermoelectric conversion device 1C of the present embodiment has a structure in which the first thermoelectric conversion element 3c and the second thermoelectric conversion element 3d are alternately connected in series to each other via each of the lower electrodes 13 and the upper electrodes 16a, 16b and 16c (the second heat transfer layer 15).

Among them, in the first thermoelectric conversion element 3c made of an n-type semiconductor, a current flows from each lower electrode 13 serving as the cold junction toward each of upper electrodes 16a, 16a and 16c (the second heat transfer layer 15) serving as the hot junction. Therefore, a current flows from an outer peripheral side of the first thermoelectric conversion element 3c to a central side thereof.

On the other hand, in the second thermoelectric conversion element 3d made of a p-type semiconductor, a current flows from each of upper electrodes 16a, 16b and 16c (the second heat transfer layer 15) serving as the hot junction toward each lower electrode 13 serving as the cold junction. Therefore, a current flows from a central side of the second thermoelectric conversion element 3d to an outer peripheral side thereof.

One terminal 4c of the pair of terminals 4c and 4d is electrically connected to one third upper electrode 16c and other terminal 4d is electrically connected to other third upper electrode 16c. Also, one the same as the electrode 5 can be used for the pair of terminals 4c and 4d.

The pair of terminals 4c and 4d are disposed on the surface of the first heat transfer layer 14 and are provided to be drawn outward from a sealed position between the substrate 2 and the first heat transfer layer 14 (the heat transfer part 6C).

In the thermoelectric conversion device 1C of the present embodiment having the configuration described above, the second heat transfer layer 15 (the heat transfer part 6C) and the thermoelectric conversion element 3 are thermally connected via the heat transfer portion 62 which protrudes toward the side facing the thermoelectric conversion element 3 in a state where a portion thereof on the side opposite to the side facing the thermoelectric conversion element 3 described above is recessed. On the other hand, a portion of the first heat transfer layer 14 is disposed as a separation portion 61 with a gap S between itself and a portion of each thermoelectric conversion element 3 and the lower electrode 13.

In this configuration, the heat source W is disposed on the surface (the heat receiving surface T) side of the heat transfer part 6C opposite to the thermoelectric conversion element 3. Also, in FIGS. 19 to 22, illustration of the heat receiving surface T and the heat source W is omitted. At this time, in the heat transfer portion 62, the distance in the thickness direction from the heat receiving surface T to the vicinity of the center serving as the hot junction of the thermoelectric conversion element 3 becomes relatively short, so that the heat H transferred from the heat source W to the heat transfer part 6C is easily transferred to the vicinity of the center of the thermoelectric conversion element 3.

On the other hand, in the separation portion 61, the distance in the thickness direction from the heat receiving surface T to the vicinity of the outer periphery serving as the cold junction of the thermoelectric conversion element 3 becomes relatively long, so that the heat H transferred from the heat source W to the heat transfer part 6C is hard to be transferred to the vicinity of the outer periphery of the conversion element 3. Thus, it is possible to obtain a high output by obtaining a large temperature difference between the hot junction and the cold junction of each thermoelectric conversion element 3.

Further, in the thermoelectric conversion device 1C of the present embodiment, the heat transfer portion 62 is formed by the second heat transfer layer 15 having a thermal conductivity higher than a thermal conductivity of the first heat transfer layer 14, and the separation portion 61 is formed by the first heat transfer layer 14 having a thermal conductivity lower than that of the second heat transfer layer 15. In this configuration, it is possible to efficiently transfer the heat H, which is transferred from the heat source W to the heat transfer part 6C, to the vicinity of the center of the thermoelectric conversion element 3 serving as the hot junction.

Further, in the thermoelectric conversion device 1C of the present embodiment, the decompressed space K is provided between the above-described first heat transfer layer 14 (the heat transfer part 6C) and a portion of each thermoelectric conversion element 3 and the lower electrode 13. This space K has the function of blocking (heat-insulating) the heat H, which is transferred from the heat source W to the heat transfer part 6C, between the vicinity of the outer periphery of each thermoelectric conversion element 3 and the first heat transfer layer 14 (separation portion 61). As a result, in the separation portion 61, since the heat H transferred from the heat source W to the heat transfer part 6C is hardly further transferred to the vicinity of the outer periphery of each thermoelectric conversion element 3, it is possible to increase the temperature difference between the hot junction and the cold junction of each thermoelectric conversion element 3, and even higher output can be obtained.

As described above, in the thermoelectric conversion device 1C of the present embodiment, similarly to the thermoelectric conversion device 1A, it is possible to efficiently transfer the heat H, which is transferred from the heat source W to the heat transfer part 6C, to the hot junction side of the thermoelectric conversion element 3 and it is possible to improve the thermoelectric conversion characteristics of the thermoelectric conversion device 1C.

### Fourth Embodiment

Next, a thermoelectric conversion device 1D shown in FIGS. 23 to 26 will be described as a fourth embodiment of the present disclosure. FIG. 23 is a transparent plan view showing a schematic configuration of the thermoelectric conversion device 1D. FIG. 24 is a cross-sectional view of the thermoelectric conversion device 1D according to the line segment A4-A4′ shown in FIG. 23. FIG. 25 is a cross-sectional view of the thermoelectric conversion device 1D according to line segment B4-B4′ shown in FIG. 23. FIG. 26 is a cross-sectional view of the thermoelectric conversion device 1D according to the line segment C4-C4′ shown in FIG. 23. In the following description, explanations for the same components as those of the thermoelectric conversion device 1A will be omitted and the same reference numerals therefor will be used in the figures.

As shown in FIGS. 23 to 26, the thermoelectric conversion device 1D of the present embodiment has a structure in which a plurality of (twenty in the present embodiment) thermoelectric conversion elements 3 disposed side by side on the surface of the substrate 2 are connected in parallel between a pair of terminals 4e and 4f.

The plurality of thermoelectric conversion elements 3 are juxtaposed in the first direction and the second direction crossing each other (orthogonal to each other in the present embodiment) in a plane on the first surface 2a side (in a specific plane) of the substrate 2. Also, in the present embodiment, five thermoelectric conversion elements 3 are provided in the first direction and four thermoelectric conversion elements 3 are provided in the second direction. Also, each thermoelectric conversion element 3 is formed in a circular shape having the same size in a plan view. Also, the plurality of thermoelectric conversion elements 3 are made of either of a p-type semiconductor or an n-type semiconductor. Also, for each thermoelectric conversion element 3, the same one as the first thermoelectric conversion element 3a or the second thermoelectric conversion element 3b can be used.

The thermoelectric conversion device 1D of the present embodiment includes a lower electrode 17 electrically connecting a plurality of thermoelectric conversion elements 3. The lower electrode 17 is formed to surround peripheries of the thermoelectric conversion elements 3 in contact with an outer peripheral portion of each thermoelectric conversion element 3. In addition, the lower electrode 17 is formed such that the outer contour thereof is in an oblong shape (a rectangular shape in the present embodiment) in a plan view. Also, one the same as the electrode 5 can be used for the lower electrode 17.

The thermoelectric conversion device 1D of the present embodiment includes a heat transfer part 6D thermally connected to a plurality of thermoelectric conversion elements 3. The heat transfer part 6D has a structure in which the first heat transfer layer 18 and the second heat transfer layer 19 are stacked in this order. Among them, the same material as that of the first heat transfer layer 8 can be used for the first heat transfer layer 18 and the same material as that of the second heat transfer layer 9 can be used for the second heat transfer layer 19.

That is, in the heat transfer part 6D of the present embodiment, the second heat transfer layer 19 has a thermal conductivity higher than a thermal conductivity of the first heat transfer layer 18. In addition, the first heat transfer layer 18 has insulating properties, and the second heat transfer layer 19 has electrical conductivity.

The first heat transfer layer 18 has an opening portion 18a at a position corresponding to a central portion of each thermoelectric conversion element 3 and a periphery of the opening portion 18a is inclined toward the substrate 2 and abuts against the thermoelectric conversion element 3. Thus, a portion of the first heat transfer layer 18 is disposed as a separation portion 61 with a gap S between itself and a portion of each thermoelectric conversion element 3 and the lower electrode 17.

In addition, at an outside of the peripheries of the plurality of thermoelectric conversion elements 3, an outer peripheral portion of the first heat transfer layer 18 is inclined toward the substrate 2 and abuts the first surface 2a. Thus, a space between the substrate 2 and the first heat transfer layer 18 (the heat transfer part 6D) is sealed.

Further, a decompressed space K is provided between the sealed substrate 2 and first heat transfer layer 18 (the heat transfer part 6D). Thus, the thermoelectric conversion device 1D has the decompressed space K in a space (at the position corresponding to the gap S) between a portion of each thermoelectric conversion element 3 and the lower electrode 13 and the first heat transfer layer 18 (the separation portion 61).

The second heat transfer layer 19 is disposed on the surface of the first heat transfer layer 18 and has an oblong shape (a rectangular shape in the present embodiment) in a plan view to overlap the lower electrode 17 in a plan view. The second heat transfer layer 19 abuts the vicinity of a center of each thermoelectric conversion element 3 through each opening portion 18a.

As a result, the second heat transfer layer 19 forms a portion of the separation portion 61 at a position covering the surface of the first heat transfer layer 18 (the position corresponding to the gap S). Also, a portion of the second heat transfer layer 19 forms a plurality of heat transfer portions 62 which protrude toward a side facing each thermoelectric conversion element 3 in a state in which a portion thereof on a side opposite to the side facing each thermoelectric conversion element 3 is recessed. The second heat transfer layer 19 (the heat transfer part 6D) is thermally connected to the vicinity of the center of the thermoelectric conversion element 3 via the heat transfer portion 62.

In addition, the second heat transfer layer 19 constitutes an upper electrode which electrically connects the plurality of thermoelectric conversion elements 3. That is, the second heat transfer layer (the upper electrode) 19 is electrically connected to the vicinity of the center of each thermoelectric conversion element 3 via the heat transfer portion 62.

Thus, the thermoelectric conversion device 1D of the present embodiment form a structure in which a plurality of thermoelectric conversion elements 3 are connected parallel to each other via the lower electrode 17 and the second heat transfer layer (the upper electrode) 19.

Here, when the thermoelectric conversion element 3 is made of an n-type semiconductor, a current flows from the lower electrode 17 side serving as a cold junction to the second heat transfer layer (the upper electrode) 19 side serving as a hot junction. Therefore, the current flows from an outer peripheral side of each thermoelectric conversion element 3 to a central side thereof. On the other hand, when the thermoelectric conversion element 3 is made of a p-type semiconductor, a current flows from the second heat transfer layer (the upper electrode) 19 side serving as the hot junction to the lower electrode 17 side serving as the cold junction. Therefore, the current flows from the outer peripheral side of each thermoelectric conversion element 3 to the central side thereof.

One terminal 4e of the pair of terminals 4e and 4f is electrically connected to the lower electrode 17, and the other terminal 4f is electrically connected to the second heat transfer layer (the upper electrode) 19. Also, one the same as the electrode 5 may be used for the pair of terminals 4e and 4f.

One terminal 4e is disposed on the first surface 2a of the substrate 2, and is provided to be drawn outward from a sealed position of the substrate 2 and the first heat transfer layer 18 (the heat transfer part 6D). Other terminal 4f is disposed on the surface of the first heat transfer layer 18, and is provided to be drawn outward from a sealed position of the substrate 2 and the first heat transfer layer 18 (the heat transfer part 6D).

In the thermoelectric conversion device 1D of the present embodiment having the configuration described above, the second heat transfer layer 19 (the heat transfer part 6D) and the thermoelectric conversion element 3 are thermally connected via the heat transfer portion 62 which protrudes toward the side facing the thermoelectric conversion element 3 in a state in which a portion thereof on the side opposite to the side facing the thermoelectric conversion element 3 described above is recessed. On the other hand, a portion of the first heat transfer layer 18 is disposed as a separation portion 61 with a gap S between itself and a portion of each thermoelectric conversion element 3 and the lower electrode 17.

In this configuration, the heat source W is disposed on the surface (the heat receiving surface T) side of the heat transfer part 6D opposite to the thermoelectric conversion element 3. Also, in FIGS. 23 to 26, illustration of the heat receiving surface T and the heat source W is omitted. At this time, in the heat transfer portion 62, the distance in the thickness direction from the heat receiving surface T to the vicinity of the center serving as the hot junction of the thermoelectric conversion element 3 becomes relatively short, so that the heat H transferred from the heat source W to the heat transfer part 6D is easily transferred to the vicinity of the center of the thermoelectric conversion element 3.

On the other hand, in the separation portion 61, the distance in the thickness direction from the heat receiving surface T to the vicinity of the outer periphery serving as the cold junction of the thermoelectric conversion element 3 becomes relatively long, so that the heat H transferred from the heat source W to the heat transfer part 6D is hard to be transferred to the vicinity of the outer periphery of the thermoelectric conversion element 3. Thus, it is possible to obtain a high output by obtaining a large temperature difference between the hot junction and the cold junction of each thermoelectric conversion element 3.

Further, in the thermoelectric conversion device 1D of the present embodiment, the heat transfer portion 62 is formed by the second heat transfer layer 19 having a thermal conductivity higher than that of the above-described first heat transfer layer 18, and the separation portion 61 is formed by the first heat transfer layer 18 having a thermal conductivity lower than that of the second heat transfer layer 19. With this configuration, it is possible to efficiently transfer the heat H, which is transferred from the heat source W to the heat transfer part 6D, to the vicinity of the center of the thermoelectric conversion element 3 serving as the hot junction.

Furthermore, in the thermoelectric conversion device 1D of the present embodiment, the decompressed space K is provided between the first heat transfer layer 18 (the heat transfer part 6D) and a portion of each thermoelectric conversion element 3 and the lower electrode 17. This space K has a function of blocking (heat insulating) the heat H, which is transferred from the heat source W to the heat transfer part 6D, between the vicinity of the outer periphery of each thermoelectric conversion element 3 and the first heat transfer layer 18 (the separation portion 61). As a result, in the separation portion 61, since the heat H transferred from the heat source W to the heat transfer part 6D is not easily further transferred to the vicinity of the outer periphery of each thermoelectric conversion element 3, it is possible to increase the temperature difference between the hot junction and the cold junction of each thermoelectric conversion element 3, and ever higher output can be obtained.

As described above, in the thermoelectric conversion device 1D of the present embodiment, similarly to the thermoelectric conversion device 1A, the heat H transferred from the heat source W to the heat transfer part 6D can be efficiently transferred toward the hot junction side of the thermoelectric conversion element 3, and it is possible to improve the thermoelectric conversion characteristics of the thermoelectric conversion device 1D.

Also, it should be noted that the present invention is not necessarily limited to the above-described embodiments, and various modifications can be made without departing from the spirit of the present invention.

For example, in the thermoelectric conversion devices 1A to 1D, although the case where the surface of the heat transfer parts 6A to 6D on the side opposite to the side facing the thermoelectric conversion element 3 is used as the heat receiving surface T is exemplified, the heat receiving surface T may be a heat radiating surface and the radiating surface side may be cooled by a cooling medium or the like.

In this case, in the thermoelectric conversion devices 1A and 1B, the distance in the thickness direction from the heat radiation surface of the heat transfer parts 6A and 6B to the second electrode 5b serving as the cold junction of the thermoelectric conversion element 3 is relatively shortened in the heat transfer portion 62, so that the heat dissipation properties on the second electrode 5b side become relatively high.

On the other hand, in the separation portion 61, the distance in the thickness direction from the heat radiation surfaces of the heat transfer parts 6A and 6B to the first electrode 5a serving as the hot junction of the thermoelectric conversion element 3 becomes relatively long, so that the heat dissipation properties on the first electrode 5a side become relatively low. Therefore, also in this case, it is possible to obtain a high output by obtaining a large temperature difference between the hot junction and the cold junction of each thermoelectric conversion element 3.

Also, in the thermoelectric conversion devices 1C and 1D, the distance in the thickness direction from the heat radiation surface of the heat transfer parts 6C and 6D to the vicinity of the center of the thermoelectric conversion element 3 serving as the cold junction of the thermoelectric conversion element 3 is relatively shortened in the heat transfer portion 62, so that the heat dissipation properties in the vicinity of the center of the thermoelectric conversion element 3 become relatively high.

On the other hand, in the separation portion 61, the distance in the thickness direction from the heat radiation surfaces of the heat transfer parts 6C and 6D to the vicinity of the outer periphery of the thermoelectric conversion element 3 serving as the hot junction of the thermoelectric conversion element 3 becomes relatively long, so that the heat dissipation properties in the vicinity of the outer periphery of the thermoelectric conversion element 3 become relatively low. Therefore, also in this case, it is possible to obtain a high output by obtaining a large temperature difference between the hot junction and the cold junction of each thermoelectric conversion element 3.

Also, each of the thermoelectric conversion devices 1A to 1D described above has the configuration in which the substrate 2 is provided. However, as long as the mechanical strength of each part can be maintained without the substrate 2, the substrate 2 may be omitted.

While preferred embodiments of the disclosure have been described and illustrated above, it should be understood that these are exemplary of the disclosure and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims

What is claimed is:

1. A thermoelectric conversion device, comprising:
at least one thermoelectric conversion element which is provided on a specific plane, and
a heat transfer part which is thermally connected to the at least one thermoelectric conversion element,
wherein the heat transfer part includes a separation portion which is disposed with a gap between the heat transfer part and at least a portion of the at least one thermoelectric conversion element, and a heat transfer portion which protrudes toward a side facing the at least one thermoelectric conversion element in a state where a portion thereof on a side opposite to the side facing the at least one thermoelectric conversion element is recessed, and is thermally connected to the at least one thermoelectric conversion element via the heat transfer portion.

2. The thermoelectric conversion device according to claim 1, wherein a space is formed at a position corresponding to the gap.

3. The thermoelectric conversion device according to claim 2, wherein the space is decompressed.

4. The thermoelectric conversion device according to claim 1, wherein the heat transfer part has a structure in which at least a first heat transfer layer and a second heat transfer layer that has a thermal conductivity higher than a thermal conductivity of the first heat transfer layer are stacked, and a portion of the second heat transfer layer forms the heat transfer portion.

5. The thermoelectric conversion device according to claim 2, wherein the heat transfer part has a structure in which at least a first heat transfer layer and a second heat transfer layer that has a thermal conductivity higher than a thermal conductivity of the first heat transfer layer are stacked, and a portion of the second heat transfer layer forms the heat transfer portion.

6. The thermoelectric conversion device according to claim 3, wherein the heat transfer part has a structure in which at least a first heat transfer layer and a second heat transfer layer that has a thermal conductivity higher than a thermal conductivity of the first heat transfer layer are stacked, and a portion of the second heat transfer layer forms the heat transfer portion.

7. The thermoelectric conversion device according to claim 1, wherein the heat transfer portion is thermally connected to one end side or other end side of the at least one thermoelectric conversion element.

8. The thermoelectric conversion device according to claim 2, wherein the heat transfer portion is thermally connected to one end side or other end side of the at least one thermoelectric conversion element.

9. The thermoelectric conversion device according to claim 3, wherein the heat transfer portion is thermally connected to one end side or other end side of the at least one thermoelectric conversion element.

10. The thermoelectric conversion device according to claim 4, wherein the heat transfer portion is thermally connected to one end side or other end side of the at least one thermoelectric conversion element.

11. The thermoelectric conversion device according to claim 5, wherein the heat transfer portion is thermally connected to one end side or other end side of the at least one thermoelectric conversion element.

12. The thermoelectric conversion device according to claim 6, wherein the heat transfer portion is thermally connected to one end side or other end side of the at least one thermoelectric conversion element.

13. The thermoelectric conversion device according to claim 7, further comprising:
at least one first electrode provided on one end side of the at least one thermoelectric conversion element; and
at least one second electrode provided on other end side of the at least one thermoelectric conversion element,
wherein the heat transfer part is thermally connected to the one end side or the other end side of the at least one thermoelectric conversion element via the heat transfer portion abutting the at least one first electrode or the at least one second electrode.

14. The thermoelectric conversion device according to claim 13,
wherein the at least one thermoelectric conversion element comprises a plurality of thermoelectric conversion elements provided in a row on the specific plane,
the at least one first electrode comprises a plurality of first electrodes and the at least one second electrode comprises a plurality of second electrodes, and
the first electrodes and the second electrodes are provided in a row in a direction of the row of the thermoelectric conversion elements.

15. The thermoelectric conversion device according to claim 1, wherein the heat transfer portion is thermally connected to a vicinity of the center of the at least one thermoelectric conversion element.

16. The thermoelectric conversion device according to claim 15,
wherein the at least one thermoelectric conversion element comprises a plurality of thermoelectric conversion elements provided in a row on the specific plane, and
the heat transfer part constitutes a portion of an electrode electrically connected to each of the thermoelectric conversion elements.

17. The thermoelectric conversion device according to claim 1, further comprising:
a substrate which has a first surface and a second surface opposed to each other in a thickness direction,
wherein the at least one thermoelectric conversion element is provided on a plane on a side of at least one of the first surface and the second surface.

18. A manufacturing method of a thermoelectric conversion device including at least one thermoelectric conversion element provided on a specific plane and a heat transfer part thermally connected to the at least one thermoelectric conversion element, the method comprising the step of forming a decompressed space between: the heat transfer part made of a first heat transfer layer and a second heat transfer layer; and at least a portion of at least one thermoelectric conversion element, wherein the step of forming a decompressed space comprises the steps of:
in forming the heat transfer part in a decompressed atmosphere,
forming a sacrificial layer covering at least a portion of a surface of the at least one thermoelectric conversion element;
forming the first heat transfer layer covering the surface of the at least one thermoelectric conversion element, on which the sacrificial layer is formed, and having an opening portion in at least a portion of a position where the sacrificial layer is formed;
removing the sacrificial layer through the opening portion; and
forming the second heat transfer layer covering the surface of the first heat transfer layer.
